(19) United States
(12) Patent Application Publication
(10) Pub. No.: US 2009/0102540 A1
(43) Pub. Date: Apr. 23, 2009

(54) SWITCH APPARATUS AND CONTROL APPARATUS

(75) Inventor: Minoru IIDA, Tokyo (JP)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ADVANTEST CORPORATION, TOKYO (JP)

(21) Appl. No.: 11/874,925

(22) Filed: Oct. 19, 2007

(51) Int. Cl. H03K 17/687

(52) U.S. Cl. 327/427

(57) ABSTRACT

There is provided a switching apparatus that switches connection or non-connection between two terminals. The switching apparatus includes a series connection FET (field effect transistor) of which a source and a drain are connected to the two terminals, and a series connection control section that supplies a series connection control signal to perform switching control between the source and the drain to a gate of the series connection FET, and once transits, when switching the series connection FET from an OFF state to an ON state, the series connection control signal from an off-state voltage to hold the OFF state to a voltage exceeding an on-state voltage to hold the ON state and then makes the series connection control signal be the on-state voltage.

### BACKGROUND

1. Technical Field

The present invention relates to a switching apparatus and a control apparatus. More particularly, the present invention relates to a switching apparatus that switches connection or non-connection between two terminals by means of a field effect transistor and a control apparatus.

2. Related Art

An FET (field effect transistor) is used as a switching apparatus for a high frequency signal. In recent years, an HEMT (high electron mobility transistor) that is an example of FET using a compound semiconductor has been broadly used as a switching apparatus for a high frequency signal.

In the meantime, FET such as HEMT has a long settling time (a time until a transit characteristic is stable) when being changed from an OFF state to an ON state. In other words, FET such as HEMT has a long time until a resistor between a source and a drain is stable by having an on-resistance value when being changed from an OFF state to an ON state.

### SUMMARY

Therefore, it is an object of some aspects of the present invention to provide a switching apparatus and a control apparatus that can solve the foregoing problems. The above and other objects can be achieved by combinations described in the independent claims. The dependent claims define further advantageous and exemplary combinations of the present invention.

To solve the above problem, according to the first aspect related to the innovations herein, one exemplary switching apparatus that switches connection or non-connection between two terminals may include: a series connection FET (field effect transistor) of which a source and a drain are connected to the two terminals; and a series connection control section that supplies a series connection control signal to perform switching control between the source and the drain to a gate of the series connection FET, and once transits, when switching the series connection FET from an OFF state to an ON state, the series connection control signal from an off-state voltage to hold the OFF state to a voltage exceeding an on-state voltage to hold the ON state and then makes the series connection control signal be the on-state voltage.

According to the second aspect related to the innovations herein, one exemplary switching apparatus that connects a common terminal and one selected from a first individual terminal and a second individual terminal may include: a first series connection FET (field effect transistor) of which a source and a drain are connected to the common terminal and the first individual terminal; a first shunt connection FET of which a source and a drain are connected to the first individual terminal and a ground; a second series connection FET of which a source and a drain are connected to the common terminal and the second individual terminal; a second shunt connection FET of which a source and a drain are connected to the second individual terminal and a ground; a first connection control section that supplies a first connection control signal to perform switching control between the source and the drain to a gate of the first series connection FET and a gate of the second shunt connection FET; and a second connection control section that supplies a second connection control signal to perform switching control between the source and the drain to a gate of the second series connection FET and a gate of the first shunt connection FET, and the first connection control section and the second connection control section: make the series connection FET connected to the selected individual terminal be an ON state; make the shunt connection FET connected to the selected individual terminal be an OFF state; make the series connection FET connected to the individual terminal which is not selected be the OFF state; make the shunt connection FET connected to the individual terminal which is not selected be the ON state; and once transit the connection control signal from an off-state voltage to hold the OFF state to a voltage exceeding an on-state voltage to hold the ON state and then make the connection control signal be the on-state voltage when switching the series connection FET and the shunt connection FET from the OFF state to the ON state.

According to the third aspect related to the innovations herein, one exemplary control apparatus that performs switching control on a field effect transistor may include a connection control section that supplies a connection control signal to perform switching control between a source and a drain to a gate of the field effect transistor, and once transits, when switching the field effect transistor from an OFF state to an ON state, the connection control signal from an off-state voltage to hold the OFF state to a voltage exceeding an on-state voltage to hold the ON state and then makes the connection control signal be the on-state voltage.

The summary does not necessarily describe all necessary features of the present invention. The present invention may also be a sub-combination of the features described above.

### BRIEF DESCRIPTION OF THE DRAWINGS

FIG. 1 is a view showing a configuration of a switching apparatus 10 according to the present embodiment.

FIG. 2 is a view exemplary showing a step signal that is changed from an off-state voltage to an on-state voltage.

FIG. 3 is a view exemplary showing insertion loss (IL) of a series connection FET 16 of which a gate is supplied with a signal of a waveform shown in FIG. 2.

FIG. 4 is a view exemplary showing insertion loss of pHEMT that is an example of a series connection FET 16 of which a gate receives a step signal.

FIG. 5 is a view exemplary showing a waveform of a series connection control signal that is changed from an off-state voltage to a voltage (over voltage) exceeding an on-state voltage and becomes the on-state voltage after a predetermined time.

FIG. 6 is a view exemplary showing insertion loss (IL) of a series connection FET 16 that is supplied with a series connection control signal with a waveform shown in FIG. 5.

FIG. 7 is a view exemplary showing insertion loss of pHEMT that is an example of a series connection FET 16 that receives a signal that is changed from −2.5V (off-state voltage) to 0.3V (over voltage) and then is changed to an on-state voltage (0V).

FIG. 8 is s view exemplary showing a waveform of a series connection control signal that is supplied to a series connection FET 16 by a series connection control section 18 according to the present embodiment.

FIG. 9 is a view exemplary showing insertion loss of a series connection FET 16 when a series connection control signal with a waveform shown in FIG. 8 is given.

FIG. 10 is a view exemplary showing insertion loss of pHEMT that is an example of a series connection FET 16.

FIG. 11 is a view exemplary showing insertion loss of pHEMT that is an example of a series connection FET 16 when its gate is supplied with a series connection control signal with a voltage waveform shown in FIG. 8.

FIG. 12 shows a first example of a configuration of a series connection control section 18 according to the present embodiment.

FIG. 13 is a view exemplary showing a configuration of a differentiating circuit 26 according to the present embodiment.

FIG. 14 shows a second example of a configuration of a series connection control section 18 according to the present embodiment.

FIG. 15 shows a third example of a configuration of a series connection control section 18 according to the present embodiment along with a series connection FET 16.

FIG. 16 shows a configuration of a switching apparatus 10 according to a first alternative example of the present embodiment.

FIG. 17 shows a configuration of a switching apparatus 10 according to a second alternative example of the present embodiment.

### DESCRIPTION OF EXEMPLARY EMBODIMENTS

The embodiments of the invention will now be described based on the preferred embodiments, which do not intend to limit the scope of the present invention, but just exemplify the invention. All of the features and the combinations thereof described in the embodiment are not necessarily essential to the invention.

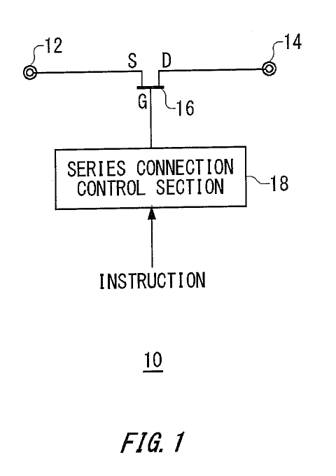

FIG. 1 is a view showing a configuration of a switching apparatus 10 according to the present embodiment. The switching apparatus 10 switches connection or non-connection between two terminals (between a terminal 12 and a terminal 14) in accordance with an instruction given from an outside. The switching apparatus 10 passes a signal between two terminals 12 and 14 in an on state and does not pass a signal between the two terminals 12 and 14 in an off state.

The switching apparatus 10 includes a series connection FET (field effect transistor) 16 and a series connection control section 18. In the present embodiment, the series connection FET 16 may be an HEMT (High Electron Mobility Transistor). Alternatively, as an example, the series connection FET 16 may be a pHEMT (Pseudomorphic HEMT).

In the series connection FET 16, its source and its drain are connected to the two terminals 12 and 14. In the series connection FET 16 of the present embodiment, the source is connected to the terminal 12 and the drain is connected to the terminal 14.

A state between the source and the drain of the series connection FET 16 becomes an ON state or an OFF state in accordance with a voltage of a signal that is given to a gate of the series connection FET 16. In the present embodiment, a state between the source and the drain of the series connection FET 16 becomes an OFF state when a voltage of −2.5V is given to the gate and becomes an ON state when a voltage of 0V is given to the gate. When the state between the source and the drain of the series connection FET 16 becomes the ON state, the two terminals 12 and 14 of the switching apparatus 10 are connected to each other. When the state between the source and the drain of the series connection FET 16 becomes the OFF state, the two terminals 12 and 14 of the switching apparatus 10 are not connected to each other.

The series connection control section 18 supplies a series connection control signal to perform switching control between the source and the drain of the series connection FET 16 to the gate of the series connection FET 16 in accordance with the instruction given from the outside. In other words, the series connection control section 18 makes the series connection control signal be an on-state voltage (for example, 0V) to hold an ON state when making the state between the source and the drain of the series connection FET 16 be an ON state. The series connection control section 18 makes the series connection control signal be an off-state voltage (for example, −2.5V) to hold an OFF state when making the state between the source and the drain of the series connection FET 16 be an OFF state.

Here, when the series connection control section 18 switches the series connection FET 16 from an OFF state to an ON state, the series connection control section 18 once transits the series connection control signal from the off-state voltage to a voltage exceeding the on-state voltage, and then transits the series connection control signal to the on-state voltage. In addition, when an on-state voltage to hold an ON state is higher than an off-state voltage to hold an OFF state, a voltage exceeding the on-state voltage means a voltage higher than the on-state voltage. On the contrary, when an on-state voltage to hold an ON state is lower than an off-state voltage to hold an OFF state, a voltage exceeding the on-state voltage means a voltage lower than the on-state voltage.

For example, if the on-state voltage is 0V and the off-state voltage is −2.5V, the series connection control section 18 once transits the series connection control signal from −2.5V to a voltage higher than 0V when switching from the OFF state to the ON state. After that, the series connection control section 18 makes the series connection control signal be 0V.

Such the switching apparatus 10 can shorten a settling time when switching the series connection FET 16 from the OFF state to the ON state. According to this, the switching apparatus 10 can quicken a speed to switch between two terminals from a non-connection state to a connected state.

In addition, as an example, when switching the series connection FET 16 from the ON state to the OFF state, the series connection control section 18 may directly transit the series connection control signal from the on-state voltage to the off-state voltage without once transiting the signal from the on-state voltage to a voltage exceeding the off-state voltage. According to this, the series connection control section 18 can easily control a voltage of a series connection control signal when switching the series connection FET 16 from an ON state to an OFF state.

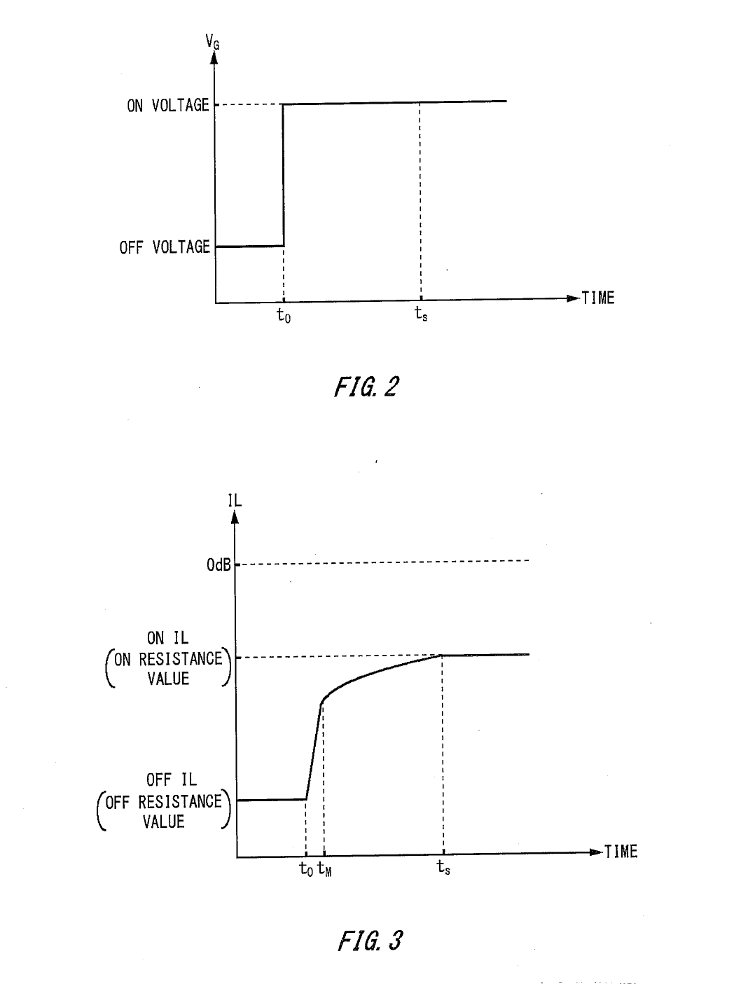

FIG. 2 is a view exemplary showing a step signal that is changed from an off-state voltage to an on-state voltage. FIG. 3 is a view exemplary showing insertion loss (IL) of the series connection FET 16 of which a gate is supplied with a signal of a waveform shown in FIG. 2.

In addition, insertion loss expresses a loss amount of a signal when the signal passes between the source and the drain. The insertion loss has a value corresponding to a resistance value between the source and the drain. The series connection FET 16 has a high resistance value between the source and the drain if the insertion loss is large and has a low resistance value between the source and the drain if the insertion loss is small.

When a stable off-state voltage is given to the gate, the insertion loss of the series connection FET 16 is stable to a predetermined value (OFF IL). Therefore, when a stable on-state voltage is given to the gate, resistance between the source and the drain of the series connection FET 16 is stable to a predetermined value (off resistance value, for example, several kQ). Moreover, when a stable on-state voltage is given to the gate, the insertion loss of the series connection FET 16 is stable to a value (ON IL) smaller than OFF IL. Therefore, when a stable on-state voltage is given to the gate, resistance between the source and the drain of the series connection FET 16 is stable to a value (on-resistance value, for example, several dozen Ω) lower than an off-resistance value.

Here, when the gate is supplied with a step signal that is changed from an off-state voltage to an on-state voltage as shown in FIG. 2, the insertion loss of the series connection FET 16 is converted from OFF IL to ON IL. In this case, the insertion loss of the series connection FET 16 is precipitously changed from a switching start time (t0) to a predetermined time (tM), and then is gently changed from the predetermined time (tM) to a settling time (ts), as shown in FIG. 3. Then, the insertion loss of the series connection FET 16 is stable to ON IL after passing the settling time (ts). In other words, when the gate is supplied with the step signal that is changed from an off-state voltage to an on-state voltage, the resistance between the source and the drain of the series connection FET 16 is firstly changed steeply, and then is comparatively gently changed. Then, the resistance between the source and the drain of the series connection FET 16 is stable to an on-resistance value after passing the settling time (ts).

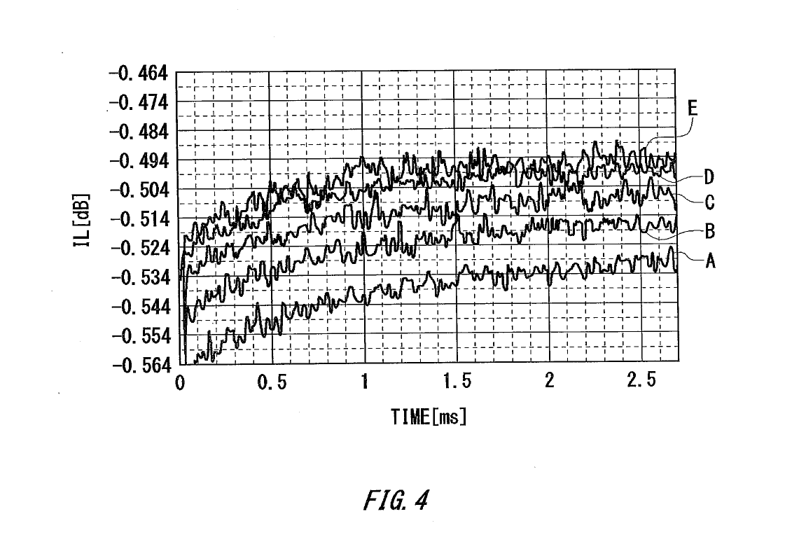

FIG. 4 is a view exemplary showing insertion loss of pHEMT (hereinafter, referred to as pHEMT according to the present example) made by Filtronic that is an example of the series connection FET 16 of which the gate receives the step signal. In addition, the pHEMT according to the present example is supplied with −2.5V as an off-state voltage and 0V as an on-state voltage.

A of FIG. 4 shows insertion loss when receiving the step signal that is changed from −2.5V (an off-state voltage) to −0.1V. B of FIG. 4 shows insertion loss when receiving the step signal that is changed from −2.5V (an off-state voltage) to −0V (an on-state voltage). C of FIG. 4 shows insertion loss when receiving the step signal that is changed from −2.5V (an off-state voltage) to 0.1V. D of FIG. 4 shows insertion loss when receiving the step signal that is changed from −2.5V (an off-state voltage) to 0.2V. E of FIG. 4 shows insertion loss when receiving the step signal that is changed from −2.5V (an off-state voltage) to 0.4V.

As shown in A to E of FIG. 4, the pHEMT according to the present example has small insertion loss as a given gate voltage is high. In other words, the pHEMT according to the present example has low resistance between the source and the drain as the given gate voltage is high. Moreover, as shown in A to E of FIG. 4, the pHEMT according to the present example has small insertion loss at a time point at which the change is switched from a steep change to a gentle change, as the given gate voltage is high. In other words, the pHEMT according to the present example has low resistance between the source and the drain at a time point at which the change is switched from a steep change to a gentle change, as the given gate voltage is high.

Moreover, as shown in A to E of FIG. 4, the pHEMT according to the present example is saturated without having small insertion loss when the given gate voltage becomes more than a steady value. In other words, the pHEMT according to the present example is saturated without having low resistance between the source and the drain when the given gate voltage becomes more than a certain steady value.

From the above, when switching the series connection FET 16 from the OFF state to the ON state, the series connection control section 18 may make a voltage of the series connection control signal be higher than the on-state voltage within a rated range capable of being given to the series connection FET 16. According to this, the switching apparatus 10 can make the resistance between the source and the drain of the series connection FET 16 be an on-resistance value at an earlier hour.

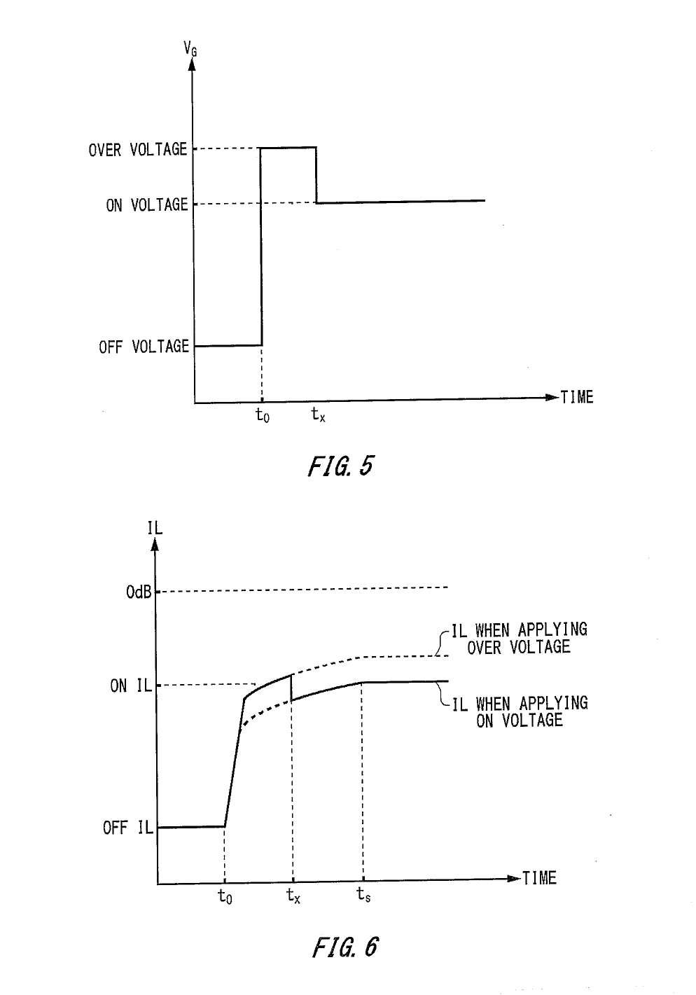

FIG. 5 is a view exemplary showing a waveform of the series connection control signal that is changed from an off-state voltage to a voltage (over voltage) exceeding an on-state voltage and becomes the on-state voltage after a predetermined time. FIG. 6 is a view exemplary showing insertion loss (IL) of the series connection FET 16 that is supplied with the series connection control signal with the waveform shown in FIG. 5.

When switching the series connection FET 16 from an OFF state to an ON state, as an example, the series connection control section 18 may first make the series connection control signal be a voltage (over voltage) exceeding the on-state voltage from a switching start time (t0) to a predetermined time (tx). In this case, the insertion loss of the series connection FET 16 from the switching start time (t0) to the predetermined time (tx) becomes small in comparison with when the step signal that is changed from the off-state voltage to the on-state voltage is given to the gate. In other words, in this case, the resistance between the source and the drain of the series connection FET 16 from the switching start time (t0) to the predetermined time (tx) becomes low in comparison with when the step signal that is changed from the off-state voltage to the on-state voltage is given to the gate.

Subsequently, at the predetermined time (tx), the series connection control section 18 may make the voltage of the series connection control signal be the on-state voltage. In this case, the insertion loss of the series connection FET 16 after the predetermined time (tx) is decreased up to the same value as insertion loss when the step signal that is changed from the off-state voltage to the on-state voltage is given to the gate. In other words, in this case, the resistance between the source and the drain of the series connection FET 16 after the predetermined time (tx) becomes the same value as that when the step signal that is changed from the off-state voltage to the on-state voltage is given to the gate.

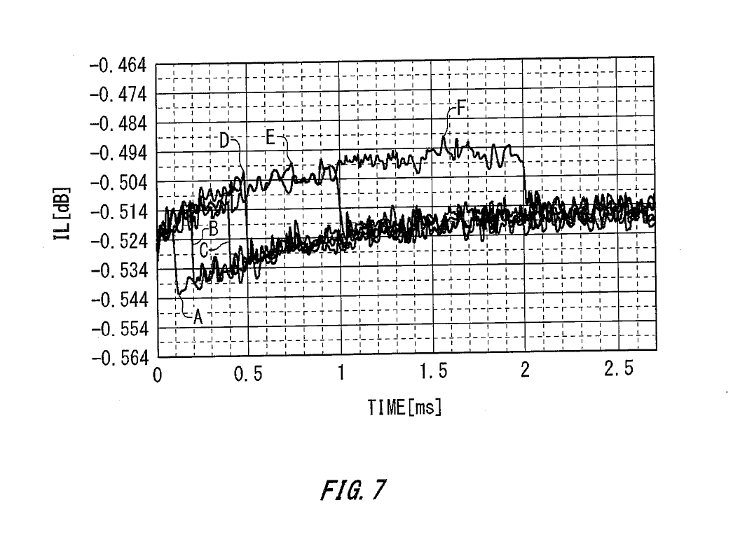

FIG. 7 is a view exemplary showing insertion loss of pHEMT according to the present example that receives a signal that is changed from −2.5V (off-state voltage) to 0.3V (over voltage) and then is changed to an on-state voltage (0V). A in FIG. 7 shows insertion loss when receiving a signal that is changed from the over voltage to the on-state voltage after 0.1 msec from the switching start time. B in FIG. 7 shows insertion loss when receiving a signal that is changed from the over voltage to the on-state voltage after 0.2 msec from the switching start time.

C in FIG. 7 shows insertion loss when receiving a signal that is changed from the over voltage to the on-state voltage after 0.4 msec from the switching start time. D in FIG. 7 shows insertion loss when receiving a signal that is changed from the over voltage to the on-state voltage after 0.5 msec from the switching start time. E in FIG. 7 shows insertion loss when receiving a signal that is changed from the over voltage to the on-state voltage after 1 msec from the switching start time. F in FIG. 7 shows insertion loss when receiving a signal that is changed from the over voltage to the on-state voltage after 2 msec from the switching start time.

As shown in A to F shown in FIG. 7, the series connection control section 18 can make the voltage of the series connection control signal be higher than the on-state voltage so as to make the resistance between the source and the drain of the series connection FET 16 be the on-resistance value at an earlier hour. However, even in this case, the series connection control section 18 returns the voltage of the series connection control signal to the on-state voltage ahead of the settling time (ts), so as to return the resistance between the source and the drain of the series connection FET 16 to a value lower than the on-resistance value. Therefore, it is preferable that the series connection control section 18 causes the voltage of the series connection control signal to be higher than the on-state voltage and then be the on-state voltage after the settling time (ts).

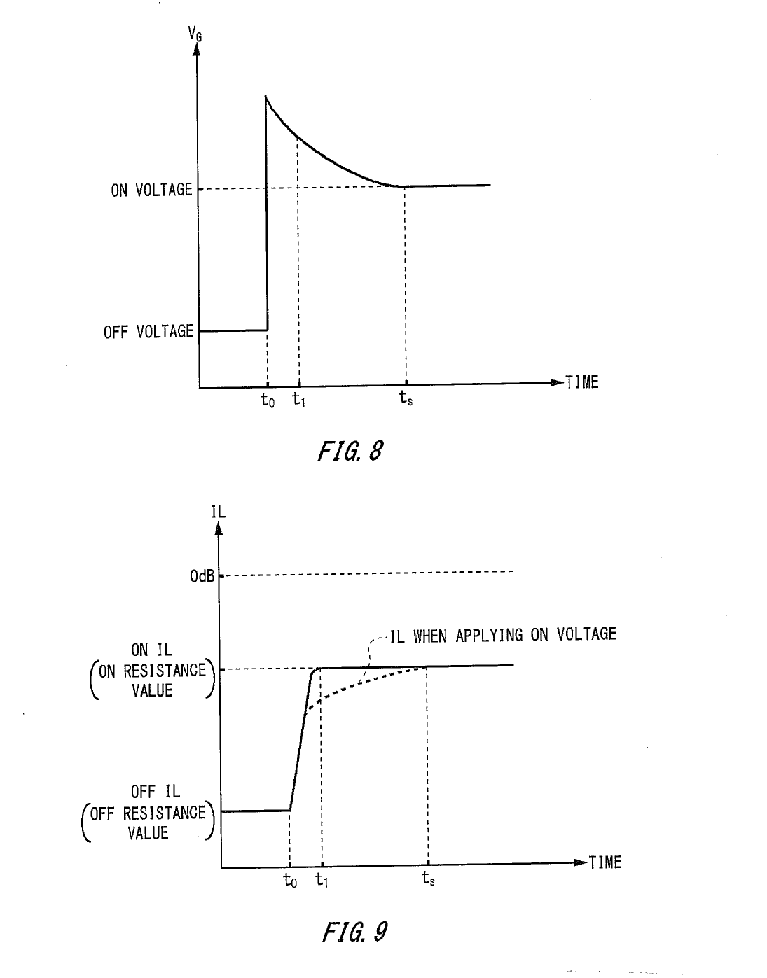

FIG. 8 is s view exemplary showing a waveform of the series connection control signal that is supplied to the series connection FET 16 by the series connection control section 18 according to the present embodiment. FIG. 9 is a view exemplary showing insertion loss of the series connection FET 16 when the series connection control signal with the waveform shown in FIG. 8 is given.

As shown in FIG. 2 to FIG. 7, the series connection FET 16 has low resistance between the source and the drain as the given gate voltage is high, and returns the resistance between the source and the drain to a value lower than the on-resistance value if making a gate voltage be high and then making the gate voltage be the on-state voltage ahead of the settling time (ts). From here onwards, it is preferable that the series connection control section 18 supplies the series connection control signal with the waveform as shown in FIG. 8 to the gate of the series connection FET 16 when switching the series connection FET 16 from the OFF state to the ON state.

In other words, when switching the series connection FET 16 from the OFF state to the ON state, the series connection control section 18 first makes the series connection control signal be the voltage exceeding the on-state voltage between a switching start time (t0) and a time (t1) at which the resistance between the source and the drain of the series connection FET 16 becomes a predetermined on-resistance value. For example, the series connection control section 18 makes the voltage of the series connection control signal be a voltage higher than the on-state voltage within a rated range of the series connection FET 16, when the on-state voltage is higher than the off-state voltage. Moreover, for example, the series connection control section 18 makes the voltage of the series connection control signal be a voltage lower than the on-state voltage within the rated range of the series connection FET 16, if the on-state voltage is lower than the off-state voltage. According to this, the series connection control section 18 can cause the resistance between the source and the drain of the series connection FET 16 to be the on-resistance value at a short time in comparison to when the step signal that is changed from the off-state voltage to the on-state voltage is given to the gate.

Subsequently, after the resistance between the source and the drain becomes the on-resistance value (after time (t1)), the series connection control section 18 gradually decreases the voltage of the series connection control signal to the on-state voltage in order to hold the resistance between the source and the drain to the on-resistance value. More specifically, after the resistance between the source and the drain becomes the on-resistance value, the series connection control section 18 gradually decreases the voltage of the series connection control signal so that the series connection control section 18 traces a voltage at which the resistance between the source and the drain seems to become on-resistance. According to this, the series connection control section 18 can hold the resistance between the source and the drain to the on-resistance value.

In addition, decreasing gradually to the on-state voltage means to gradually reduce a voltage to the on-state voltage when the on-state voltage is higher than the off-state voltage. Moreover, decreasing gradually to the on-state voltage means to gradually increase a voltage to the on-state voltage when the on-state voltage is lower than the off-state voltage.

Then, after gradually decreasing the voltage of the series connection control signal up to the on-state voltage, the series connection control section 18 holds a state in which the voltage of the series connection control signal is the on-state voltage. According to this, the series connection control section 18 can hold the series connection FET 16 in a stable ON state.

When switching the series connection FET 16 from the OFF state to the ON state, such the switching apparatus 10 can shorten a time until the resistance between the source and the drain becomes the on-resistance value, and further hold a stable ON state after the resistance between the source and the drain becomes the on-resistance value. According to this, the switching apparatus 10 can switch the series connection FET 16 from the OFF state to the ON state at high speed.

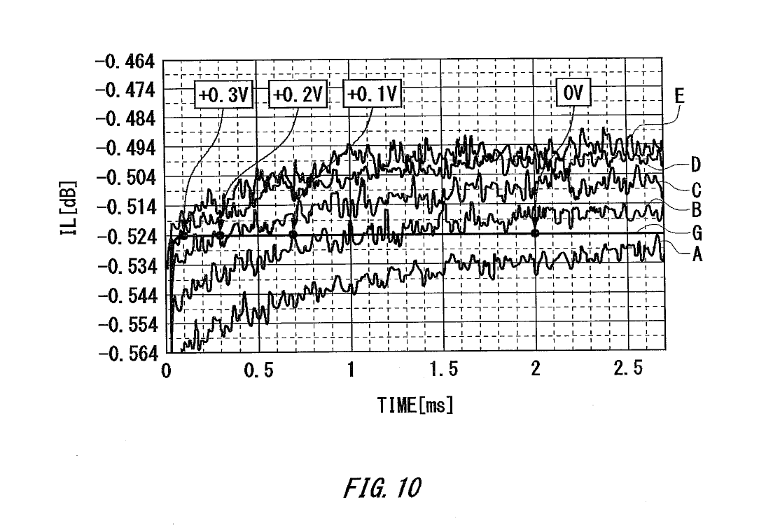

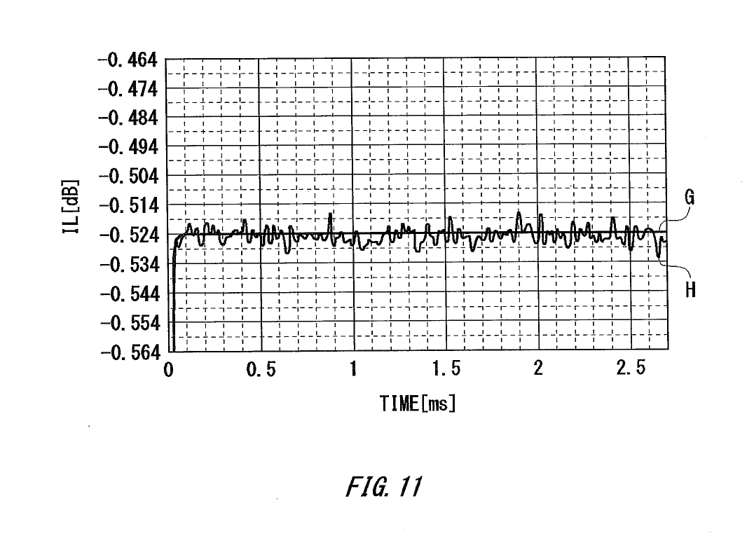

FIG. 10 and FIG. 11 are views exemplary showing insertion loss of pHEMT according to the present example. A to E of FIG. 10 show an example of insertion loss of pHEMT according to the present example when supplying a gate voltage similar to that of FIG. 4.

G of FIGS. 10 and 11 shows a simulation result of insertion loss of pHEMT according to the present example when the series connection control signal with the voltage waveform shown in FIG. 8 is given to the gate. Moreover, H of FIG. 11 shows a measurement result of insertion loss of pHEMT according to the present example when the series connection control signal with the voltage waveform shown in FIG. 8 is given to the gate. More in detail, G of FIG. 10 and FIG. 11 show insertion loss when changing the gate voltage from −2.5V (an off-state voltage) to 0.3V (a voltage exceeding the on-state voltage) and then gradually decreasing the gate voltage to 0V (an on-state voltage) with a derivative waveform of the step signal.

As shown in G of FIG. 10 and FIG. 11, when the series connection control signal with the voltage waveform shown in FIG. 8 is given to the gate, the resistance between the source and the drain of pHEMT according to the present example becomes an on-resistance value in 0.12 msec and then has a stable resistance value. In this manner, by giving the series connection control signal with the voltage waveform as shown in FIG. 8, the series connection control section 18 can shorten a time until the resistance between the source and the drain of the series connection FET 16 becomes the on-resistance value and further hold a stable ON state afterward.

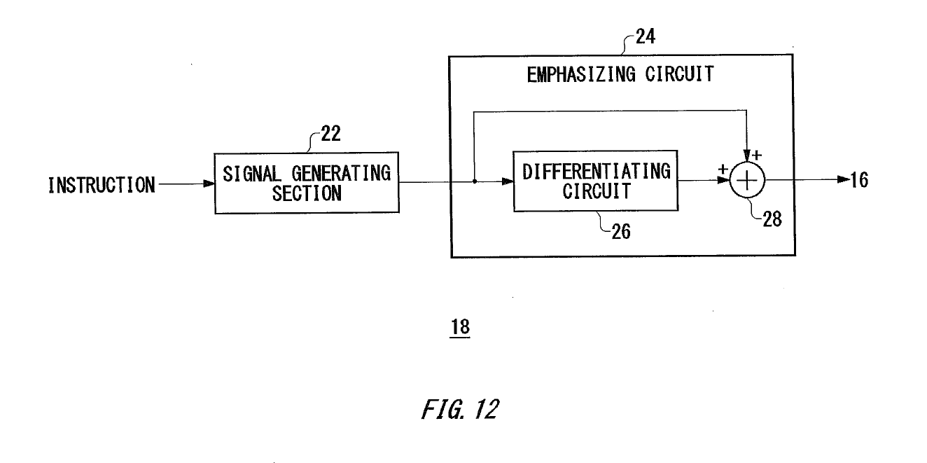

FIG. 12 shows a first example of a configuration of the series connection control section 18 according to the present embodiment. As an example, when switching the series connection FET 16 from the OFF state to the ON state, the series connection control section 18 may supply to the gate of the series connection FET 16 a signal obtained by adding a step signal, which is changed from the off-state voltage to the on-state voltage and then is constant at the on-state voltage, and a emphatic signal of the step signal, as the series connection control signal. Such the series connection control section 18 can generate the series connection control signal that once transits from the off-state voltage to the voltage exceeding the on-state voltage and then becomes the on-state voltage when switching the series connection FET 16 from the OFF state to the ON state.

As an example, the series connection control section 18 may have a signal generating section 22 and an emphasizing circuit 24. The signal generating section 22 generates a step signal that is changed from the off-state voltage to the on-state voltage and then is constant at the on-state voltage when an instruction to switching from the OFF state to the ON state is given from an outside.

The emphasizing circuit 24 includes a differentiating circuit 26 and an adding circuit 28. The differentiating circuit 26 outputs a differential signal which is obtained by differentiating a step signal output from the signal generating section 22. The adding circuit 28 gives a signal obtained by adding the step signal output from the signal generating section 22 and the differential signal output from the differentiating circuit 26 to the gate of the series connection FET 16 as the series connection control signal. In this way, the emphasizing circuit 24 can give a signal obtained by adding the step signal and an emphatic signal of this step signal to the gate of the series connection FET 16.

In addition, as an example, when an instruction to switching the series connection FET 16 from the ON state to the OFF state is given from an outside, the emphasizing circuit 24 may the step signal output from the signal generating section 22 to the gate of the series connection FET 16 without adding the step signal to the differential signal. According to this, when switching the series connection FET 16 from the ON state to the OFF state, the series connection control section 18 can generate the series connection control signal that is changed from the on-state voltage to the off-state voltage and then is constant at the off-state voltage.

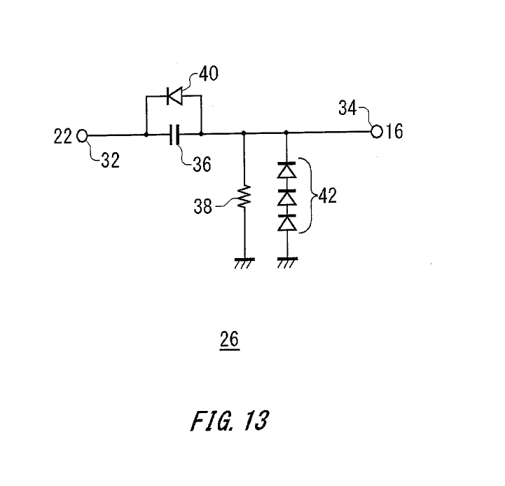

FIG. 13 is a view exemplary showing a configuration of the differentiating circuit 26 according to the present embodiment. As an example, the differentiating circuit 26 may include an input port 32, an output port 34, a capacitor 36, a resistor 38, a capacitor-side diode 40, and an output-side diode 42. The input port 32 inputs the step signal from the signal generating section 22. The output port 34 outputs the series connection control signal to the series connection FET 16.

The capacitor 36 is connected between the input port 32 and the output port 34. In the capacitor-side diode 40, its anode is connected to the output port 34 and its cathode is connected to a ground. The capacitor-side diode 40 passes a minus voltage from the input port 32 to the output port 34 and restricts a plus voltage.

In the output-side diode 42, its anode is connected to the ground and its cathode is connected to the output port 34. The output-side diode 42 restricts amplitude of the minus voltage that is output from the output port 34. Such the differentiating circuit 26 can differentiate a signal input from the input port 32 and output the differentiated signal from the output port 34.

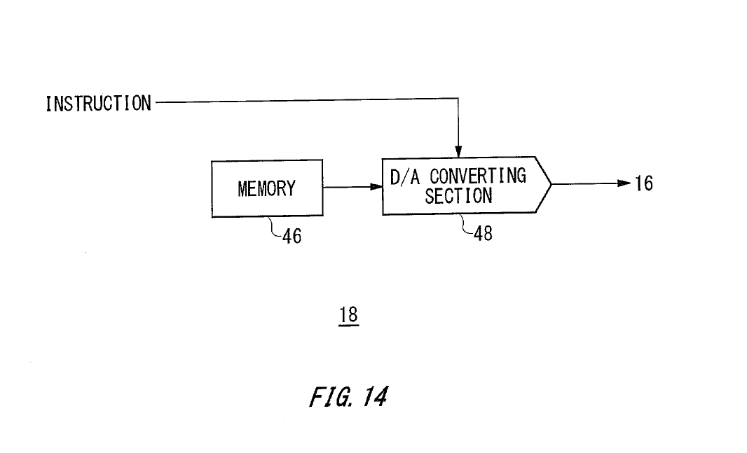

FIG. 14 shows a second example of a configuration of the series connection control section 18 according to the present embodiment. As an example, the series connection control section 18 may have a memory 46 and a D/A converting section 48.

The memory 46 stores waveform data expressing a waveform of a series connection control signal that once transits from the off-state voltage to a voltage exceeding the on-state voltage and then becomes the on-state voltage. When a switching instruction from OFF to ON is given, the D/A converting section 48 digital-to-analog converts the waveform data stored on the memory 46 and gives a signal according to the waveform data to the gate as the series connection control signal. Such the series connection control section 18 can supply to the gate of the series connection FET 16 the series connection control signal with the waveform that once transits from the off-state voltage to the voltage exceeding the on-state voltage and then becomes the on-state voltage.

Moreover, as an example, the memory 46 may further store waveform data expressing a waveform of a series connection control signal that becomes the off-state voltage without once transiting from the on-state voltage to the voltage exceeding the off-state voltage. Then, as an example, when a switching instruction from ON to OFF is given, the D/A converting section 48 may digital-to-analog convert the waveform data stored on the memory 46 and supply to the gate the series connection control signal that becomes the off-state voltage without once transiting from the on-state voltage to the voltage exceeding the off-state voltage.

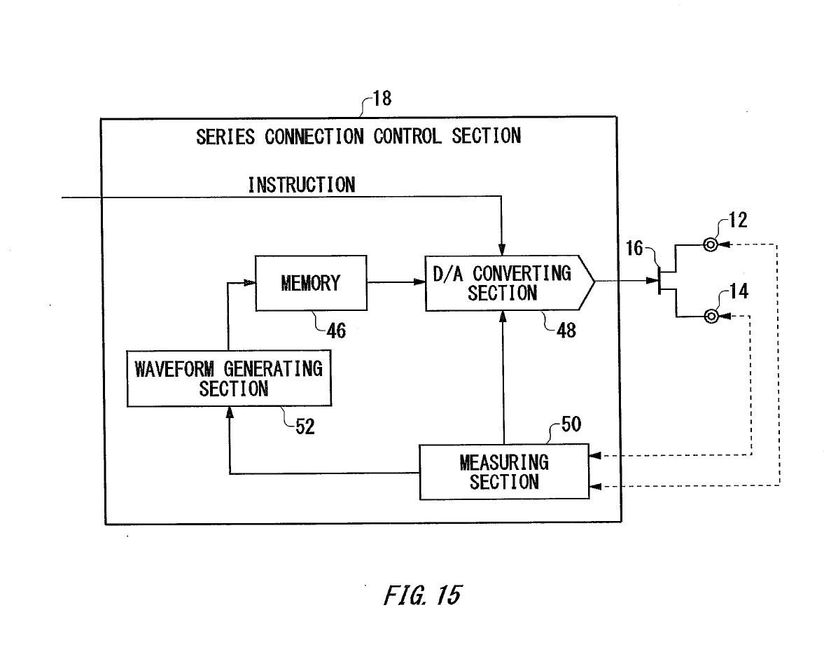

FIG. 15 shows a third example of a configuration of the series connection control section 18 according to the present embodiment along with the series connection FET 16. As an example, the series connection control section 18 may have a memory 46, a D/A converting section 48, a measuring section 50, and a waveform generating section 52. Since the memory 46 and the D/A converting section 48 have the substantially same configuration and function as those of the memory 46 and the D/A converting section 48 according to the second example shown in FIG. 14, detailed descriptions are omitted.

The measuring section 50 measures a characteristic of resistance between the source and the drain of the series connection FET 16 from the switching start time to the settling time when switching the series connection FET 16 from the OFF state to the ON state. As an example, the measuring section 50 supplies to the gate of the series connection FET 16 a plurality of step signals that is changed from the off-state voltage to a plurality of voltages different from one another, and measures a characteristic of resistance between the source and the drain of the series connection FET 16 as shown in FIG. 10, for example.

The waveform generating section 52 generates waveform data according to the measurement result by the measuring section 50, and writes the waveform data into the memory 46. As an example, the waveform generating section 52 generates waveform data expressing a gate voltage waveform that causes the resistance between the source and the drain to be gradually decreased so as to hold the resistance to the on-resistance value, and writes the waveform data into the memory 46, on the basis of the characteristic shown in FIG. 10, for example. In this way, the series connection control section 18 can cause the memory 46 to store the waveform data expressing the waveform of the series connection control signal.

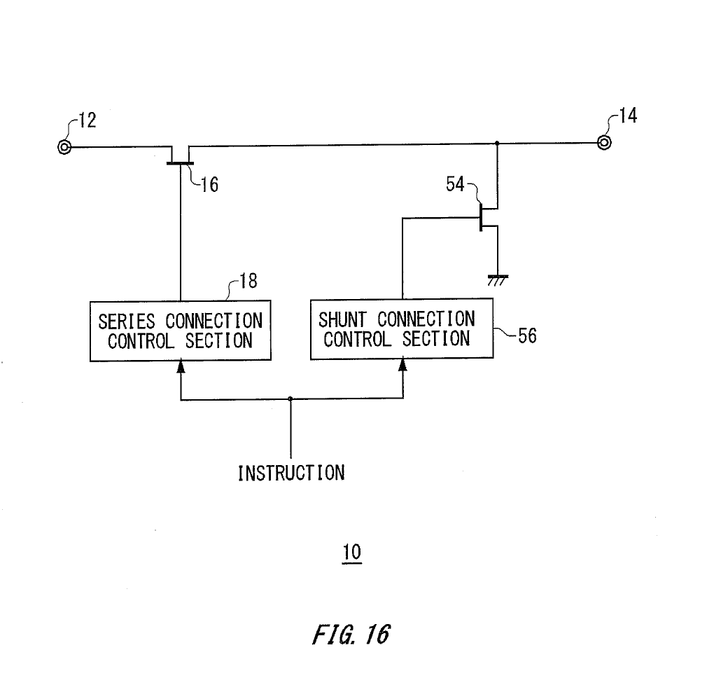

FIG. 16 shows a configuration of a switching apparatus 10 according to a first alternative example of the present embodiment. Since the switching apparatus 10 according to the present alternative example has the substantially same configuration and function as those of the switching apparatus 10 shown in FIG. 1 according to the present embodiment, members having the substantially same configuration and function as those of the members included in the switching apparatus 10 according to the present embodiment have the same reference numerals and their descriptions will be omitted except the following differences.

The switching apparatus 10 according to the present alternative example includes a series connection FET 16, a series connection control section 18, a shunt connection FET 54, and a shunt connection control section 56. The shunt connection FET 54 may be the same kind of device as the series connection FET 16. In the present embodiment, the shunt connection FET 54 may be HEMT. Alternatively, as an example, the shunt connection FET 54 may be pHEMT.

A source and a drain of the shunt connection FET 54 are respectively connected to one terminal of two terminals 12 and 14 and a ground. In the present embodiment, the source and the drain of the shunt connection FET 54 are connected to the terminal 14 and the ground.

In the shunt connection FET 54, a state between the source and the drain becomes an ON state or an OFF state in accordance with a voltage of a signal given to its gate. When the state between the source and the drain becomes the ON state, the terminal 14 and the ground are connected to each other. When the state between the source and the drain becomes the OFF state, the terminal 14 and the ground are not connected to each other.

The shunt connection control section 56 supplies a shunt connection control signal to perform switching control between the source and the drain of the shunt connection FET 54 to the gate of the shunt connection FET 54 in accordance with an instruction given from an outside. In other words, when setting the state between the source and the drain of the shunt connection FET 54 to the ON state, the shunt connection control section 56 makes the shunt connection control signal be an on-state voltage. When setting the state between the source and the drain of the shunt connection FET 54 to the OFF state, the shunt connection control section 56 makes the shunt connection control signal be an off-state voltage.

Here, when the series connection FET 16 is changed from the OFF state to the ON state, the shunt connection control section 56 switches the shunt connection FET 54 from the ON state to the OFF state. Moreover, when the series connection FET 16 is changed from the ON state to the OFF state, the shunt connection control section 56 switches the shunt connection control section 56 from the OFF state to the ON state. According to this, in the switching apparatus 10 according to the first alternative example, the terminal 14 is connected to the ground in non-connection. Therefore, the switching apparatus 10 according to such the first alternative example can increase an insulating property between two terminals 12 and 14 in non-connection, and thus realize a series-shunt type switching apparatus which can control passing and blocking of a high frequency signal.

Furthermore, when switching the shunt connection FET 54 from the OFF state to the ON state, the shunt connection control section 56 makes the shunt connection control signal be the on-state voltage without once transiting the shunt connection control signal from the off-state voltage to a voltage exceeding the on-state voltage. In case of the series-shunt type switching apparatus, the influence by which a switching speed of the shunted FET is given to a total switching speed of the switching apparatus is smaller than the influence by which a switching speed of the serialized FET is given to the total switching speed. Therefore, the switching apparatus 10 according to the present alternative example can simply control the shunt connection FET 54 without having an influence on a speed to switch the state between two terminals from a non-connection state to a connection state.

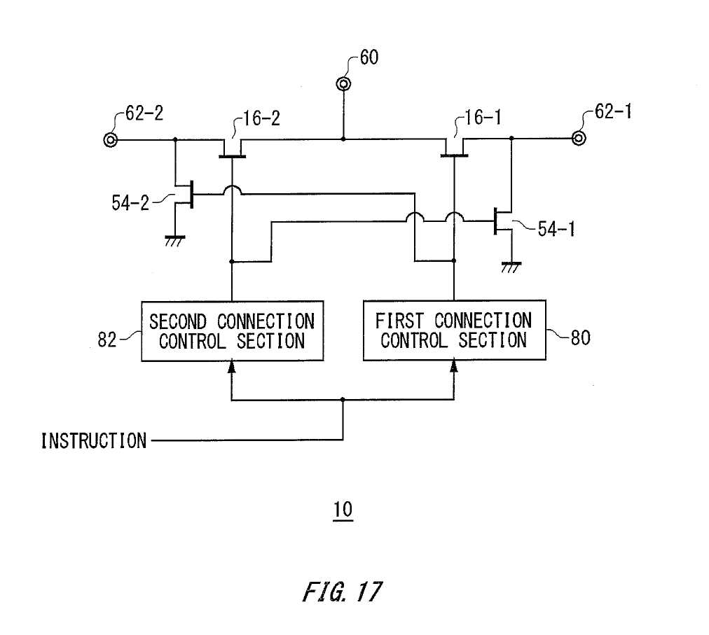

FIG. 17 shows a configuration of a switching apparatus 10 according to a second alternative example of the present embodiment. Since the switching apparatus 10 according to the present alternative example has the configuration and function substantially same as those of the switching apparatus 10 according to the first alternative example shown in FIG. 16, members having the substantially same configuration and function as those of the members included in the switching apparatus 10 according to the first alternative example have the same reference numerals and their descriptions will be omitted except the following differences.

The switching apparatus 10 according to the present alternative example connects one selected from a first individual terminal 62-1 and a second individual terminal 62-2 and a common terminal 60 in accordance with an instruction given from an outside. More in detail, the switching apparatus 10 connects the common terminal 60 and the first individual terminal 62-1 and does not connect the common terminal 60 and the second individual terminal 62-2, when the first individual terminal 62-1 is selected. Moreover, the switching apparatus 10 connects the common terminal 60 and the second individual terminal 62-2 and does not connect the common terminal 60 and the first individual terminal 62-1 when the second individual terminal 62-2 is selected.

The switching apparatus 10 includes a first series connection FET 16-1, a first shunt connection FET 54-1, a second series connection FET 16-2, a second shunt connection FET 54-2, a first connection control section 80, and a second connection control section 82. A source and a drain of the first series connection FET 16-1 are respectively connected to the common terminal 60 and the first individual terminal 62-1. A source and a drain of the first shunt connection FET 54-1 are respectively connected to the first individual terminal 62-1 and a ground. A source and a drain of the second series connection FET 16-2 are respectively connected to the common terminal 60 and the second individual terminal 62-2. A source and a drain of the second shunt connection FET 54-2 are respectively connected to the second individual terminal 62-2 and a ground.

The first connection control section 80 supplies a first connection control signal to perform switching control between the source and the drain of each of the first series connection FET 16-1 and the second shunt connection FET 54-2 to gates of the first series connection FET 16-1 and the second shunt connection FET 54-2 in accordance with an instruction given from an outside. The second connection control section 82 supplies a second connection control signal to perform switching control between the source and the drain of each of the second series connection FET 16-2 and the first shunt connection FET 54-1 to gates of the second series connection FET 16-2 and the first shunt connection FET 54-1 in accordance with an instruction given from an outside.

More in detail, the first connection control section 80 and the second connection control section 82 make the series connection FET 16 connected to the selected individual terminal 62 be an ON state, and also make the shunt connection FET 54 connected to the selected individual terminal 62 be an OFF state. Furthermore, the first connection control section 80 and the second connection control section 82 make the series connection FET 16 connected to the individual terminal 62 that is not selected be an OFF state, and also make the shunt connection FET 54 connected to the individual terminal 62 that is not selected be an ON state.

In other words, the first connection control section 80 causes the first series connection FET 16-1 and the second shunt connection FET 54-2 to be ON when the first individual terminal 62-1 is selected according to the instruction given from the outside. Furthermore, the second connection control section 82 causes the second series connection FET 16-2 and the first shunt connection FET 54-1 to be OFF when the first individual terminal 62-1 is selected according to the instruction given from the outside. Similarly, when the second individual terminal 62-2 is selected according to the instruction given from the outside, the first connection control section 80 causes the first series connection FET 16-1 and the second shunt connection FET 54-2 to be OFF. Furthermore, when the second individual terminal 62-2 is selected according to the instruction given from the outside, the second connection control section 82 causes the second series connection FET 16-2 and the first shunt connection FET 54-1 to be ON. The switching apparatus 10 according to such the present alternative example can realize an SPDT (Single Pole Double Throw) switch.

Here, the first connection control section 80 and the second connection control section 82 execute control similar to that of the series connection control section 18. In other words, when switching the first series connection FET 16-1 and the second shunt connection FET 54-2 from an OFF state to an ON state, the first connection control section 80 once transits the first connection control signal from an off-state voltage to a voltage exceeding an on-state voltage and then makes the first connection control signal be the on-state voltage. Similarly, when switching the second series connection FET 16-2 and the first shunt connection FET 54-1 from the OFF state to the ON state, the second connection control section 82 once transits the second connection control signal from the off-state voltage to the voltage exceeding the on-state voltage and then makes the second connection control signal be the on-state voltage. The switching apparatus 10 according to such the present alternative example can shorten a settling time when switching the first series connection FET 16-1 and the second series connection FET 16-2 from the OFF state to the ON state. According to this, the switching apparatus 10 can quicken a switching speed of the SPDT switch.

Although the present invention has been described by way of an exemplary embodiment, it should be understood that those skilled in the art might make many changes and substitutions without departing from the spirit and the scope of the present invention. It is obvious from the definition of the appended claims that embodiments with such modifications also belong to the scope of the present invention.

What is claimed is:

1. A switching apparatus that switches connection or non-connection between two terminals, comprising:
a series connection FET (field effect transistor) of which a source and a drain are connected to the two terminals; and
a series connection control section that supplies a series connection control signal to perform switching control between the source and the drain to a gate of the series connection FET, and once transits, when switching the series connection FET from an OFF state to an ON state, the series connection control signal from an off-state voltage to hold the OFF state to a voltage exceeding an on-state voltage to hold the ON state and then makes the series connection control signal be the on-state voltage.

2. The switching apparatus as claimed in claim 1, wherein the series connection control section makes the series connection control signal be a voltage exceeding the on-state voltage until resistance between the source and the drain of the series connection FET becomes a predetermined on-resistance value, and gradually decreases a voltage of the series connection control signal up to the on-state voltage in order to hold the resistance between the source and the drain to the on-resistance value after the resistance between the source and the drain becomes the on-resistance value.

3. The switching apparatus as claimed in claim 1, wherein the series connection control section supplies, when switching the series connection FET from the OFF state to the ON state, a signal obtained by adding a step signal, which is changed from the off-state voltage to the on-state voltage and then is constant at the on-state voltage, and an emphatic signal of the step signal to the gate as the series connection control signal.

4. The switching apparatus as claimed in claim 3, wherein the series connection control section comprises:
a signal generating section that generates the step signal that is changed from the off-state voltage to the on-state voltage and then is constant at the on-state voltage; and
an emphasizing circuit that supplies to the gate a signal that is obtained by adding the step signal and a differential signal obtained by differentiating the step signal as the series connection control signal.

5. The switching apparatus as claimed in claim 1, wherein the series connection control section comprises:
a memory that stores waveform data expressing a waveform of the series connection control signal that once transits from the off-state voltage to the voltage exceeding the on-state voltage and then becomes the on-state voltage; and
a D/A converting section that supplies a signal according to the waveform data to the gate as the series connection control signal when a switching instruction from OFF to ON is given.

6. The switching apparatus as claimed in claim 5, wherein the D/A converting section supplies to the gate the series connection control signal that is changed from the on-state voltage to the off-state voltage and then is constant at the off-state voltage when a switching instruction from ON to OFF is given.

7. The switching apparatus as claimed in claim 5, further comprising:
a measuring section that measures a characteristic of the resistance between the source and the drain of the series connection FET when switching from the OFF state to the ON state; and
a waveform generating section that generates the waveform data according to a measurement result by the measuring section and writes the waveform data into the memory.

8. The switching apparatus as claimed in claim 1, wherein the switching apparatus further comprises:
a shunt connection FET of which a source and a drain are connected to one terminal of the two terminals and a ground; and
a shunt connection control section that supplies a shunt connection control signal to perform switching control between the source and the drain to a gate of the shunt connection FET, and
the shunt connection control section:
switches the shunt connection FET from the ON state to the OFF state when the series connection FET is changed from the OFF state to the ON state; and
makes the shunt connection control signal be the on-state voltage without once transiting the shunt connection control signal from the off-state voltage to the voltage exceeding the on-state voltage when switching the shunt connection FET from the OFF state to the ON state.

9. A switching apparatus that connects a common terminal and one selected from a first individual terminal and a second individual terminal, the switching apparatus comprising:
a first series connection FET (field effect transistor) of which a source and a drain are connected to the common terminal and the first individual terminal;
a first shunt connection FET of which a source and a drain are connected to the first individual terminal and a ground;
a second series connection FET of which a source and a drain are connected to the common terminal and the second individual terminal;
a second shunt connection FET of which a source and a drain are connected to the second individual terminal and a ground;
a first connection control section that supplies a first connection control signal to perform switching control between the source and the drain to a gate of the first series connection FET and a gate of the second shunt connection FET; and
a second connection control section that supplies a second connection control signal to perform switching control between the source and the drain to a gate of the second series connection FET and a gate of the first shunt connection FET, and
the first connection control section and the second connection control section:
make the series connection FET connected to the selected individual terminal be an ON state;
make the shunt connection FET connected to the selected individual terminal be an OFF state;
make the series connection FET connected to the individual terminal which is not selected be the OFF state;
make the shunt connection FET connected to the individual terminal which is not selected be the ON state; and
once transit the connection control signal from an off-state voltage to hold the OFF state to a voltage exceeding an on-state voltage to hold the ON state and then make the connection control signal be the on-state voltage when switching the series connection FET and the shunt connection FET from the OFF state to the ON state.

10. A control apparatus that performs switching control on a field effect transistor, comprising a connection control section that supplies a connection control signal to perform switching control between a source and a drain to a gate of the field effect transistor, and once transits, when switching the field effect transistor from an OFF state to an ON state, the connection control signal from an off-state voltage to hold the OFF state to a voltage exceeding an on-state voltage to hold the ON state and then makes the connection control signal be the on-state voltage.
